(19) United States
(12) Patent Application Publication
(10) Pub. No.: US 2019/0363307 A1
(43) Pub. Date: Nov. 28, 2019

(54) LIGHT EMITTING SUBSTRATE AND MANUFACTURING METHOD THEREOF, LIGHT EMITTING DEVICE AND MANUFACTURING METHOD THEREOF

(71) Applicants: HEFEI XINSHENG OPTOELECTRONICS TECHNOLOGY CO., LTD., Hefei (CN); BOE TEACHNOLOGY GROUP CO., LTD., Beijing (CN)

(72) Inventor: Xuelian CHENG, Beijing (CN)

(21) Appl. No.: 16/268,456

(22) Filed: Feb. 5, 2019

(30) Foreign Application Priority Data
May 23, 2018 (CN) 201810501080.7

(51) Int. Cl. H01L 51/56; H01L 51/52

(52) U.S. Cl. CPC H01L 51/56; H01L 51/5212; H01L 51/5203

(57) ABSTRACT

Provided are a light emitting substrate and a manufacturing method thereof, a light emitting device and a manufacturing method thereof. The manufacturing method of a light emitting substrate includes: forming a first electrode layer on a base substrate by one patterning process; forming a metal layer on the base substrate formed with the first electrode layer by one patterning process, the metal layer includes a first metal layer formed on the first electrode layer and a second metal layer which is formed on the base substrate and separated from the first electrode layer; forming a light emitting layer on the first metal layer; forming a second electrode layer on the base substrate formed with the light emitting layer, the second electrode layer is formed on the light emitting layer and on the second metal layer.

### CROSS REFERENCE TO RELATED APPLICATIONS

The present application claims the priority of the Chinese Patent Application with the Application No. 201810501080.7 filled May 23, 2018, which is incorporated herein in the entire by reference.

### TECHNICAL FIELD

The present disclosure relates to the field of display technology, in particular to a light emitting substrate and a manufacturing method thereof, a light emitting device and a manufacturing method thereof.

### BACKGROUND

An OLED light emitting structure is a self-luminous structure without a backlight, which can remarkably reduce power consumption compared with other light emitting structures.

In a conventional design for the OLED light emitting structure, generally, it is required to provide a first ITO structure (a structure made of indium tin oxide materials) as an anode in a light emitting region, and two second ITO structures are provided at both sides of the light emitting region, which are not coupled to the first ITO structure. The two second ITO structures are coupled to a cathode of the OLED in a peripheral region around the light emitting region, and are coupled to a peripheral flexible printed circuit board (FPC) via cathode wires provided at the peripheral region. At present, three array masks, which are used to manufacture the anode, an auxiliary anode and a pixel defining layer (PDL), respectively, are generally required for manufacturing the above OLED light emitting structure.

### SUMMARY

The present disclosure provides a light emitting substrate and a manufacturing method thereof, a light emitting device and a manufacturing method thereof.

In an aspect, the present disclosure provides a manufacturing method of a light emitting substrate, comprising steps of: forming a first electrode layer on one surface of a base substrate by one patterning process; forming a metal layer on the base substrate on which the first electrode layer has been formed by one patterning process, wherein the metal layer comprises a first metal layer which is formed on a surface of the first electrode layer away from the base substrate and a second metal layer which is formed on the one surface of the base substrate and separated from the first electrode layer; forming a light emitting layer on a surface of the first metal layer away from the base substrate; and forming a second electrode layer on the base substrate on which the light emitting layer has been formed, the second electrode layer is formed on a surface of the light emitting layer away from the base substrate and on a surface of the second metal layer away from the base substrate.

In an embodiment of the present disclosure, the first electrode layer is formed on one surface of the base substrate by using an open mask; and the metal layer is formed on the base substrate on which the first electrode layer has been formed by using an array mask.

In an embodiment of the present disclosure, the first metal layer is formed as an auxiliary anode for the first electrode layer.

In an embodiment of the present disclosure, the step of forming a metal layer on the base substrate comprises a step of forming two second metal layers on the base substrate at opposite sides of the first electrode layer.

In an embodiment of the present disclosure, the second electrode layer is formed on the base substrate on which the light emitting layer has been formed by using an open mask.

In an embodiment of the present disclosure, the open masks used to form the first electrode layer and the second electrode layer are masks with regular patterns.

In an embodiment of the present disclosure, the open masks used to form the first electrode layer and the second electrode layer are masks with rectangle patterns.

In an embodiment of the present disclosure, the first metal layer is formed into a grid shape, and the second metal layer is formed into the grid shape or a block shape.

In an embodiment of the present disclosure, the first electrode layer is formed as an anode and the second electrode layer is formed as a cathode.

In an embodiment of the present disclosure, the manufacturing method of a light emitting substrate further includes a step of forming a pixel defining layer on the base substrate on which the metal layer has been formed after forming the metal layer, wherein the pixel defining layer is formed on a surface of the first metal layer away from the base substrate and on the one surface of the base substrate.

In an embodiment of the present disclosure, the pixel defining layer is formed, by using an array mask, on the base substrate on which the metal layer has been formed, wherein the pixel defining layer extends along a portion of the first metal layer and separates the first electrode layer from the second metal layer.

In an embodiment of the present disclosure, after forming the second electrode layer, the method further comprises a step of: successively forming a packaging adhesive layer and a packaging substrate on the base substrate on which the second electrode layer has been formed, wherein the packaging adhesive layer is formed on a surface of the second electrode layer away from the base substrate and on a surface of the second metal layer away from the base substrate; and the packaging substrate is formed on a surface of the packaging adhesive layer away from the base substrate.

In an aspect, the present disclosure provides a manufacturing method of a light emitting device, which includes the above manufacturing method of the light emitting substrate.

In an aspect, the present disclosure provides a light emitting substrate, including: a base substrate; a first electrode layer provided on one surface of the base substrate; a metal layer provided on the base substrate provided with the first electrode layer, wherein the metal layer comprises a first metal layer which is provided on a surface of the first electrode layer away from the base substrate and a second metal layer which is provided on the one surface of the base substrate and separated from the first electrode layer; a light emitting layer provided on a surface of the first metal layer away from the base substrate; and a second electrode layer provided on the base substrate provided with the light emitting layer, the second electrode layer is provided on a surface of the light emitting layer away from the base substrate and on a surface of the second metal layer away from the base substrate.

In an embodiment of the present disclosure, the second metal layer comprises two second metal layers which are provided at opposite sides of the first electrode layer.

In an embodiment of the present disclosure, the first metal layer is configured as an auxiliary anode for the first electrode layer.

In an embodiment of the present disclosure, the first metal layer is of a grid shape, and the second metal layer is of a grid shape or a block shape.

In an embodiment of the present disclosure, the first electrode layer is configured as an anode and the second electrode layer is configured as a cathode.

In an embodiment of the present disclosure, the light emitting substrate further includes a pixel defining layer provided on the base substrate provided with the metal layer, wherein the pixel defining layer is provided on a surface of the first metal layer away from the base substrate and on the one surface of the base substrate, and the pixel defining layer extends along a portion of the first metal layer and separates the first electrode layer from the second metal layer.

In an aspect, the present disclosure provides a light emitting device, which includes the above light emitting substrate.

### BRIEF DESCRIPTION OF DRAWINGS

FIG. 1A is a top view of a light emitting substrate with a packaging part removed in the related art;

FIG. 1B is a partial section view taken along a line A-A in FIG. 1A;

FIG. 2 is a flowchart illustrating a manufacturing method of a light emitting substrate according to an embodiment of the present disclosure;

FIG. 3 is a top view of a light emitting substrate with a packaging part removed according to an embodiment of the present disclosure;

FIG. 4 is a partial section view taken along a line B-B in FIG. 3; and

FIG. 5 is a partial section view of the light emitting substrate used in an embodiment of the present disclosure.

### DETAIL DESCRIPTION OF EMBODIMENTS

A light emitting substrate and a manufacturing method thereof, a light emitting device and a manufacturing method thereof in the present disclosure will be described in details below in conjunction with the accompanying drawings such that those skilled in the art can understand the technical solutions of the present disclosure better.

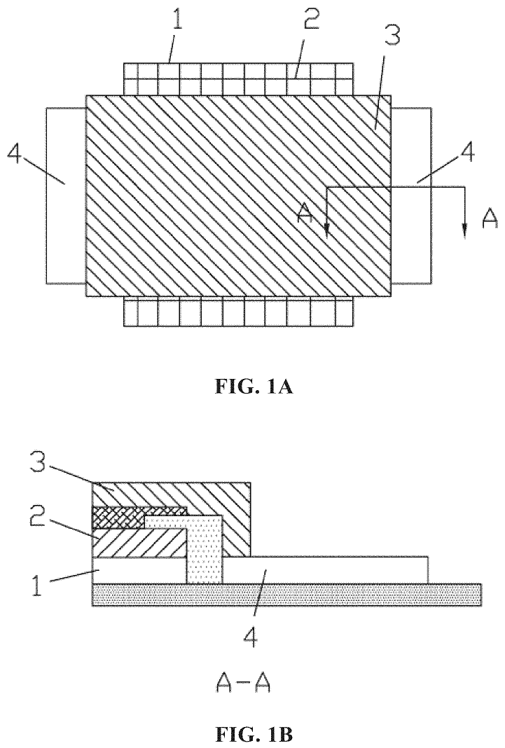

FIG. 1A is a top view of a light emitting substrate with a package part removed in the related art, and FIG. 1B is a partial section view taken along a line A-A in FIG. 1A. Referring to FIG. 1A and FIG. 1B, a conventional OLED light emitting substrate is shown, generally, an anode 1 made of ITO (indium tin oxide materials) is provided in a light emitting region, and two ITO structures 4 are provided at both sides of the light emitting region, which are not coupled to the anode 1 located between the two ITO structures 4. The two ITO structures 4 are coupled to a cathode 3 of the light emitting substrate in a peripheral region around the light emitting region, and are coupled to a peripheral flexible printed circuit board (FPC) (not shown) via cathode wires provided at the peripheral region. The anode 1 is coupled to the FPC via an anode wire. Further, an auxiliary anode 2 is provided on the anode 1, which reduces a sheet resistance of the anode 1.

At present, three array masks, which are used to manufacture the anode, the auxiliary anode and a pixel defining layer (PDL), respectively, are generally required to manufacture the conventional OLED light emitting substrate. However, the cost of three array masks is high, resulting in a too high cost of the OLED light emitting substrate.

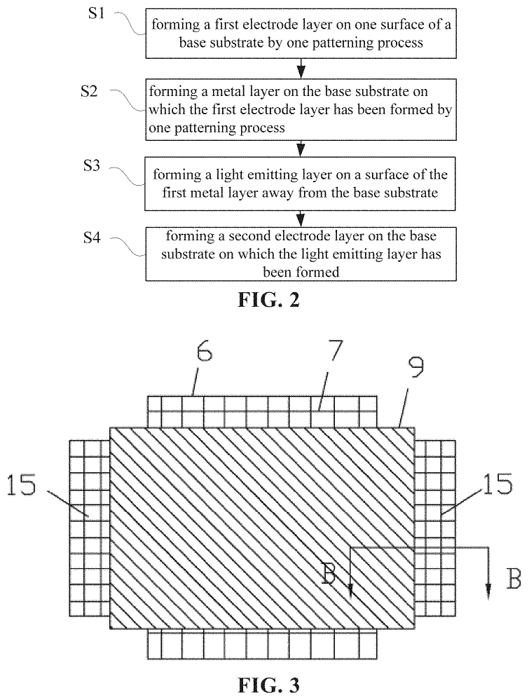

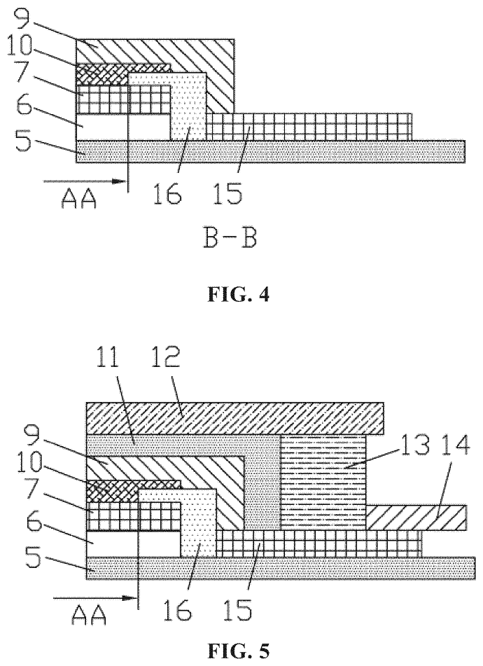

FIG. 2 is a flowchart illustrating a manufacturing method of a light emitting substrate according to an embodiment of the present disclosure, FIG. 3 is a top view of a light emitting substrate with a packaging part removed according to an embodiment of the present disclosure, FIG. 4 is a partial section view taken along a line B-B in FIG. 3, and FIG. 5 is a partial section view of the light emitting substrate used in an embodiment of the present disclosure, with a packaging part. A manufacturing method of a light emitting substrate according to an embodiment of the present disclosure will be described in details below by referring to FIG. 2 and in conjunction with FIGS. 3 through 5. The manufacturing method includes the following steps S1-S4.

At the step S1, a first electrode layer 6 is formed on one surface of a base substrate 5 by a patterning process. In an implementation of the present disclosure, the base substrate 5 may be a glass substrate.

At the step S2, a metal layer is formed on the base substrate 5 on which the first electrode layer 6 has been formed by a single patterning process, the metal layer includes a first metal layer 7 which is formed on a surface of the first electrode layer 6 away from the base substrate 5 and at least one second metal layer 15 which is formed on the one surface of the base substrate 5 and separated from the first electrode layer 6.

The first metal layer 7 acts as an auxiliary anode of the first electrode layer 6, which reduces a sheet resistance of the first electrode layer 6. In the present embodiment of the present disclosure, two second metal layers 15 are provided at opposite sides of the first electrode layer 6.

At the step S3, a light emitting layer 10 is formed on a surface of the first metal layer 7 away from the base substrate 5.

At the step S4, a second electrode layer 9 is formed on the base substrate 5 on which the light emitting layer 10 has been formed, the second electrode layer 9 is formed on a surface of the light emitting layer 10 away from the base substrate 5 and on a surface of the second metal layers 15 away from the base substrate 5. The second electrode layer 9 extends into a peripheral region and is coupled to the above second metal layers 15, so as to electrically couple the second electrode layer 9 to a peripheral flexible printed circuit board (FPC) 14, as shown in FIG. 5.

In an embodiment of the present disclosure, after the above step S2 and before the step S3, the manufacturing method further includes the following steps: a pixel defining layer 16 is formed on the base substrate 5 on which the metal layers have been formed, the pixel defining layer 16 is formed on a surface of the first metal layer 7 away from the base substrate 5 and on the one surface of the base substrate 5. The pixel defining layer 16 extends along a portion of the first metal layer 7 and separates the first electrode layer 6 from the second metal layers 15.

The above first electrode layer 6 is only an entire surface structure located in the light emitting region, such that the above first electrode layer 6 may be manufactured by using an open mask with regular patterns, the first metal layer 7 and the two second metal layers 15 and the pixel defining layer 16 may be manufactured by using two array masks, respectively. Due to simple structure of the open mask, the cost of the open mask is much lower than that of the array mask, such that the cost for manufacturing the light emitting substrate may be reduced significantly. The second electrode layer 9 is also formed by an open mask.

The above second metal layers 15 may be in a better contact with the second electrode layer 9, such that the conductivity of the second electrode layer 9 can be improved and thus, the capacity for transmitting signals can be improved.

In practice, the above first electrode layer 6 may be used as the anode, the second electrode layer 9 may be used as the cathode, and the first metal layer 7 may be used as an auxiliary anode of the anode.

It should be noted that the above first electrode layer 6 is electrically coupled to a peripheral flexible printed circuit board (FPC) 14 via an anode wire.

In an embodiment of the present disclosure, the first electrode layer 6 is formed in the light emitting region of the base substrate 5 by using the open mask, which is a mask with regular patterns, such as a mask with a rectangle open (pattern). Due to the simple structure of the open mask, the cost of the mask is much lower than that of the array mask. The above first electrode layer 6 is generally made of the ITO material.

In an embodiment of the present disclosure, the above metal layers (the first metal layer 7 and two second metal layers 15) are formed on the base substrate 5 on which the first electrode layer 6 has been formed by using the array mask. The metal layers are mainly of a Mo/Al/Mo structure. Further, the first metal layer 7 is formed into a grid shape, and the second metal layers 15 are formed into a grid shape or a block shape, such that the sheet resistance of the first electrode layer 6 may be reduced, an etching load may be reduced, and the second metal layers of the grid shape is in a better contact with the second electrode layer 9, thus, the conductivity of the second electrode layer 9 can be improved and thus, the capacity of transmitting signals is improved. In other embodiments of the present disclosure, the first electrode layer 6 and the first metal layer 7 may be formed by using other materials. Alternatively, in other embodiments of the present disclosure, the first electrode layer 6 may be formed by using metal materials and the first metal layer 7 may be formed by using ITO materials.

In an embodiment of the present disclosure, the pixel defining layer 16 is formed on the base substrate 5 on which the metal layers have been formed by using the array mask.

In an embodiment of the present disclosure, the second electrode layer 9 is formed on the base substrate 5 on which the light emitting layer 10 has been formed by using the open mask. The second electrode layer 9 is generally made of Al. In other embodiments of the present disclosure, the second electrode layer 9 is formed by using other materials.

In an embodiment of the present disclosure, after a second electrode layer 9 is formed on the base substrate 5 on which the light emitting layer 10 has been formed (the step S4), the manufacturing method further includes the following steps: a packaging adhesive layer and a packaging substrate 12 are successively formed on the base substrate 5 on which the second electrode layer 9 has been formed, as shown in FIG. 5. The packaging adhesive layer is formed on a surface of the second electrode layer 9 away from the base substrate 5 and on surfaces of the second metal layers 15 away from the base substrate 5. The packaging substrate 12 is formed on a surface of the packaging adhesive layer away from the base substrate 5. The packaging adhesive layer includes a liquid adhesive 11 and a dam 13. An operating principle of the structure in the embodiment of the present disclosure is that the second electrode layer 9 acting as the cathode is coupled to the second metal layers 15 at both sides of the second electrode layer 9, as shown in FIG. 3. Furthermore, the second metal layers 15 are coupled to the peripheral flexible printed circuit board (FPC) 14, as shown in FIG. 5, such that signals for the cathode are input via the metal layers. The first electrode layer 6 acting as the anode is coupled to the first metal layer 7, such that signals for the anode are input via the metal layer, so that light may be emitted.

The present disclosure has the following beneficial effects:

The present disclosure relates to a light emitting substrate and a manufacturing method thereof, a light emitting device and a manufacturing method thereof. The above first electrode layer is only one entire surface structure located in the light emitting region, such that the above first electrode layer may be manufactured by an open mask with regular patterns. Due to the simple structure of the open mask, the cost of the open mask is much lower than that of the army mask, such that the sheet resistance of the first electrode layer may be reduced, an etching load may be reduced, and the second metal layers of the grid shape are in a better contact with the second electrode layer, thus, the conductivity of the second electrode layer can be improved and thus, the capacity of transmitting signals is improved.

As another technical solution, the present disclosure also provides a manufacturing method of a light emitting device, which includes the above manufacturing method of the light emitting substrate provided by the present disclosure.

By using the above manufacturing method of the light emitting substrate provided by the present disclosure, the cost of manufacturing the light emitting device may be reduced largely, the sheet resistance of the first electrode layer may be reduced, an etching load may be reduced, and the second metal layers of grid shape are in a better contact with the second electrode layer, thus, the conductivity of the second electrode layer can be improved and the capacity of transmitting signals of the second electrode layer is improved.

As another technical solution, the present disclosure also provides a light emitting substrate, as shown in FIGS. 3 and 4, the light emitting substrate includes: a base substrate 5; a first electrode layer 6 provided on one surface of the base substrate 5; a metal layer provided on the base substrate 5 provided with the first electrode layer 6, the metal layer include a first metal layer 7 which is provided on a surface of the first electrode layer 6 away from the base substrate 5 and at least one second metal layer 15 which is provided on the one surface of the base substrate 5 and separated from the first electrode layer 6; a light emitting layer 10 provided on a surface of the first metal layer 7 away from the base substrate 5; and a second electrode layer 9 provided on the base substrate 5 provided with the light emitting layer 10, the second electrode layer 9 is provided on a surface of the light emitting layer 10 away from the base substrate 5 and on a surface of the second metal layer 15 away from the base substrate 5.

It should be noted that as shown in FIGS. 4 and 5, the light emitting layer 10 includes a portion located in the whole light emitting region AA and a portion located in a region outside the light emitting region AA (a peripheral region). In other words, an area of an orthographic projection of the light emitting layer 10 on the base substrate 5 is greater than an area of an orthographic projection of the light emitting region AA on the base substrate

The first metal layer 7 acts as an auxiliary anode of the first electrode layer 6, which reduces a sheet resistance of the first electrode layer 6. In an embodiment of the present disclosure, two second metal layers 15 are provided at the opposite sides of the first electrode layer 6. The second electrode layer 9 is coupled to the above second metal layers 15, so as to electrically couple the second electrode layer 9 to a peripheral flexible printed circuit board (FPC) 14.

In an embodiment of the present disclosure, the first metal layer 7 and the two second metal layers 15 are mainly of a Mo/Al/Mo structure. Further, the first metal layer 7 is formed into a grid shape, and the second metal layers 15 are formed into the grid shape or a block shape, such that the sheet resistance of the first electrode layer 6 may be reduced, an etching load may be reduced, and the second metal layers of grid shape is in a better contact with the second electrode layer 9, thus, the conductivity of the second electrode layer 9 can be improved and thus, the capacity of transmitting signals of the second electrode layer 9 is improved.

In an embodiment of the present disclosure, the light emitting substrate further includes a pixel defining layer 16 provided on the base substrate 5 provided with the metal layers. The pixel defining layer 16 is provided on a surface of the first metal layer 7 away from the base substrate 5 and on the one surface of the base substrate 5. The pixel defining layer 16 extends along a portion of the first metal layer 7 and separates the first electrode layer 6 from the second metal layers 15.

FIG. 5 shows a partial section view of the light emitting substrate which has been packaged according to an embodiment of the present disclosure. A packaging adhesive layer and a packaging substrate 12 are successively provided on the light emitting substrate in FIG. 4. The packaging adhesive layer includes a liquid adhesive 11 and a dam 13.

As another technical solution, the present disclosure also provides a light emitting device, which includes the above light emitting substrate provided by the present disclosure.

By using the above light emitting substrate provided by the present disclosure, the cost of manufacturing the light emitting device can be reduced largely, such that the sheet resistance of the first electrode layer may be reduced, an etching load may be reduced, and the second metal layers of grid shape may be in a better contact with the second electrode layer, thus, the conductivity of the second electrode layer can be improved and thus, the capacity of transmitting signals of the second electrode layer can be improved.

It should be understood that the above embodiments are merely exemplary embodiments used only for illustrating the principle of the present disclosure. However, the present disclosure is not limited thereto. Obviously, those skilled in the art can make various modifications and variants to this disclosure without departing from spirit and scope of this disclosure. As such, if these modifications and variants of this disclosure fall into the scope of the claims and their equivalents, the present disclosure intends to include these modifications and variants.

What is claimed is:

1. A manufacturing method of a light emitting substrate, comprising steps of:
forming a first electrode layer on one surface of a base substrate by one patterning process;
forming a metal layer on the base substrate on which the first electrode layer has been formed by one patterning process, wherein the metal layer comprises a first metal layer which is formed on a surface of the first electrode layer away from the base substrate and a second metal layer which is formed on the one surface of the base substrate and separated from the first electrode layer;
forming a light emitting layer on a surface of the first metal layer away from the base substrate; and
forming a second electrode layer on the base substrate on which the light emitting layer has been formed, the second electrode layer is formed on a surface of the light emitting layer away from the base substrate and on a surface of the second metal layer away from the base substrate.

2. The manufacturing method of a light emitting substrate of claim 1, wherein the first electrode layer is formed on one surface of the base substrate by using an open mask; and
the metal layer is formed on the base substrate on which the first electrode layer has been formed by using an array mask.

3. The manufacturing method of a light emitting substrate of claim 1, wherein the first metal layer is formed as an auxiliary anode for the first electrode layer.

4. The manufacturing method of a light emitting substrate of claim 1, wherein the step of forming a metal layer on the base substrate comprises a step of forming two second metal layers on the base substrate at opposite sides of the first electrode layer.

5. The manufacturing method of a light emitting substrate of claim 1, wherein the second electrode layer is formed on the base substrate on which the light emitting layer has been formed by using an open mask.

6. The manufacturing method of a light emitting substrate of claim 5, wherein the open masks used to form the first electrode layer and the second electrode layer are masks with regular patterns.

7. The manufacturing method of a light emitting substrate of claim 6, wherein the open masks used to form the first electrode layer and the second electrode layer are masks with rectangle patterns.

8. The manufacturing method of a light emitting substrate of claim 1, wherein the first metal layer is formed into a grid shape, and the second metal layer is formed into the grid shape or a block shape.

9. The manufacturing method of a light emitting substrate of claim 1, wherein the first electrode layer is formed as an anode and the second electrode layer is formed as a cathode.

10. The manufacturing method of a light emitting substrate of claim 1, further comprising a step of:
forming a pixel defining layer on the base substrate on which the metal layer has been formed after forming the metal layer,
wherein the pixel defining layer is formed on a surface of the first metal layer away from the base substrate and on the one surface of the base substrate.

11. The manufacturing method of a light emitting substrate of claim 10, wherein the pixel defining layer is formed, by using an array mask, on the base substrate on which the metal layer has been formed, wherein the pixel defining layer extends along a portion of the first metal layer and separates the first electrode layer from the second metal layer.

12. The manufacturing method of a light emitting substrate of claim 1, wherein after forming the second electrode layer, the method further comprises a step of:
successively forming a packaging adhesive layer and a packaging substrate on the base substrate on which the second electrode layer has been formed, wherein the packaging adhesive layer is formed on a surface of the second electrode layer away from the base substrate and on a surface of the second metal layer away from the base substrate; and the packaging substrate is formed on a surface of the packaging adhesive layer away from the base substrate.

13. A manufacturing method of a light emitting device, which comprises the manufacturing method of the light emitting substrate of claim 1.

14. A light emitting substrate, comprising:
a base substrate:
a first electrode layer provided on one surface of the base substrate;
a metal layer provided on the base substrate provided with the first electrode layer, wherein the metal layer comprises a first metal layer which is provided on a surface of the first electrode layer away from the base substrate and a second metal layer which is provided on the one surface of the base substrate and separated from the first electrode layer;
a light emitting layer provided on a surface of the first metal layer away from the base substrate; and
a second electrode layer provided on the base substrate provided with the light emitting layer, the second electrode layer is provided on a surface of the light emitting layer away from the base substrate and on a surface of the second metal layer away from the base substrate.

15. The light emitting substrate of claim 14, wherein the second metal layer comprises two second metal layers which are provided at opposite sides of the first electrode layer.

16. The light emitting substrate of claim 14, wherein the first metal layer is configured as an auxiliary anode for the first electrode layer.

17. The light emitting substrate of claim 14, wherein the first metal layer is of a grid shape, and the second metal layer is of a grid shape or a block shape.

18. The light emitting substrate of claim 14, wherein the first electrode layer is configured as an anode and the second electrode layer is configured as a cathode.

19. The light emitting substrate of claim 4, further comprising a pixel defining layer provided on the base substrate provided with the metal layer, wherein the pixel defining layer is provided on a surface of the first metal layer away from the base substrate and on the one surface of the base substrate, and the pixel defining layer extends along a portion of the first metal layer and separates the first electrode layer from the second metal layer.

20. A light emitting device, which comprises the light emitting substrate of claim 14.
